(19) United States
(12) Patent Application Publication
(10) Pub. No.: US 2009/0212818 A1
(43) Pub. Date: Aug. 27, 2009

(54) Integrated circuit design method for improved testability

(75) Inventors: Shouichi Sakai, Kanagawa (JP); Yoshinobu Irie, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/379,411

(22) Filed: Feb. 20, 2009

(30) Foreign Application Priority Data
Feb. 27, 2008 (JP) 2008-046720

(51) Int. Cl. H03K 19/173; G06F 17/50; H03K 19/00

(52) U.S. Cl. 326/46; 716/17; 716/12; 326/93

(57) ABSTRACT

An integrated circuit design method includes: classifying flipflops arranged around a macro based on a netlist of a integrated circuit incorporating the flipflops and the macro; and generating a flipflop-replaced netlist from the netlist. In classifying the flipflops, a flipflop which is connected to an input terminal of the macro directly or through an input-side logic cone and operated on the same clock signal as the macro is classified as a control type, and a flipflop which has a data output connected to an input terminal of the macro directly or through the input-side logic cone and operated on a different clock signal is classified as a hold type. In the flipflop-replaced netlist, the flipflop classified as the control type is replaced with a control flipflop which is configurable to toggle a data output thereof in synchronization with the clock signal by configuring a control input separately provided a data input thereof, and the flipflop classified as the hold type is replaced with a first hold flipflop which is configurable to hold data so that the data hold therein is unchanged.

### INCORPORATION BY REFERENCE

This application claims the benefit of priority based on Japanese Patent Application No. 2008-046720, filed on Feb. 27, 2008, the disclosure of which is incorporated herein by reference.

### BACKGROUND OF THE INVENTION

1. Field of the Invention

The present invention relates to an integrated circuit design method, and more particularly, relates to a design-for-testability technique for improving the easiness of a macro boundary test.

2. Description of the Related Art

The macro boundary test, which involves detecting a delay error between a macro and a user logic circuit, is one of the important elemental technologies in the LSI (Large Scale Integrated Circuit) product development. In recent LSIs, many macros are integrated therein and this often causes a considerable increase in the circuit scale. Such situation necessitates the verification of signal interfacing timings among macros in order to ensure the reliability of the LSIs.

Japanese Laid Open Patent Application No. JP-A 2006-337289 (hereinafter, referred to as the '289 application) discloses a technique for executing a macro boundary test, specifically, a technique for detecting a delay error between a logic and a memory. This technique is directed to detect delay errors by switching signal paths, one of which is a signal path for executing a memory test with a memory BIST (built in self test) circuit, and the other is a signal path which provides a connection between a logic circuit and a memory.

FIG. 1 is a circuit diagram showing the configuration of an integrated circuit disclosed in the '289 application. The integrated circuit shown in FIG. 1 is provided with a logic circuit 118 and an embedded memory 117. The logic circuit 118 provides the memory access to the memory 117. The logic circuit 118 and the memory 117 are both provided along a scan path used for executing the test. In detail, flipflops 101 and 104 are integrated within the logic circuit 118 for signal interfacing with the memory 117. The flipflops 101 and 104 are connected in series to be incorporated into a part of the scan path, when the integrated circuit is placed into a test mode. It should be noted that the flipflops 101 and 104 are configured to be operated in synchronization with an internal clock signal. A selector 105 is provided between the memory 117 and the logic circuit 118. The memory 117 is allowed to be connected to a memory BIST circuit 110 through the selector 105. Integrated within the memory BIST circuit 110 are flipflops 113 and 114 which are incorporated within the scan path and this provides an access from the flipflops 113 and 114 to the memory 117.

A flipflop 122, which is also incorporated within the scan path, is connected to the input of the memory 117. The flipflop 122 is associated with the memory input 102, and the flipflop 122 receives and holds the input signal fed to the memory input 102 for the memory access.

The memory 117 is adapted to a write-through mode. When the memory 117 is placed into the write-through mode (namely, when a write through mode signal 120 is enabled), a write circuit is activated for a write operation, and a read circuit is also activated. For example, a data is written onto a selected memory cell with a write amplifier and a sense amplifier both activated, and, and the data stored in the memory cell is identified by the sense amplifier. Such operations result in that the output value of the flipflop 122 within the memory 117 is written onto a memory cell array 119, and the same data as the output value is read from the memory cell array 119 and outputted from the memory output 103.

In FIG. 1, the signal path for which a delay error between the memory 117 and the logic circuit 118 is to be detected is indicated by a solid line. The delay error is detected as follows: A scan clock signal with a relatively low frequency is externally supplied and test data are serially inputted to the flipflops 101, 104 and 122 through scan inputs 108 and 115 in synchronization with the scan clock signal. This is followed by testing the logic circuit 118 and the memory 117 by feeding the test data in parallel from the flipflops 101, 104 and 122 in synchronization with the internal clock signal, which has a frequency identical to that in the actual operation. Specifically, the data outputted from the flipflop 101 in the logic circuit 118 is latched by the flipflop 122 in the memory 117. The data latched by the flipflop 122 is externally outputted from the scan output 116. The delay error between the flipflop 101, which operates as the output stage of the logic circuit 118, and the flipflop 122, which operates as the input stage of the memory 117, is detected on the basis of the externally-outputted data. Moreover, the delay error between the flipflop 122 and the flipflop 104 in the logic circuit 118 is detected as follows: Firstly, the write through mode signal 120 is enabled to place the memory 117 into the write-through mode. Test data which are scan-inputted to the flipflop 122 within the memory 117 are used as the input data for the memory access. The output data (write data) of the flipflop 122 passes through the memory cell array 119, and is latched by the flipflop 104 in the logic circuit 118 through the memory output 103. The data latched by the flipflop 104 is externally outputted from the scan output 109. The delay error between the flipflop 122 and the flipflop 104 in the logic circuit 118 is detected on the basis of the data latched by the flipflop 104.

The inventors have discovered that one issue of this conventional method of the macro boundary test is that a large number of test patterns are required to implement the macro boundary test with high quality. For the semiconductor integrated circuit in FIG. 1, for example, the delay error between the flipflop 122 in the memory 117 and the flipflop 104 in the logic circuit 118 can be detected by only using a reduced number of test patterns. However, a large number of test patterns are required to detect the delay error between the flipflop 101 in the logic circuit 118 and the flipflop 122 in the memory 117. This is because the detection of the delay error between the flipflop 101 in the logic circuit 118 and the flipflop 122 in the memory 117 requires the output data of the flipflop 101 to be toggled at the frequency of the actual operation and this necessitates generating the test patterns so as to control all the data inputs of the logic cones connected to the data input of the flipflop 101.

### SUMMARY

In an aspect of the present invention, an integrated circuit design method includes: classifying flipflops arranged around a macro based on a netlist of a integrated circuit incorporating the flipflops and the macro; and generating a flipflop-replaced netlist from the netlist. In classifying the flipflops, a flipflop which is connected to an input terminal of the macro directly or through an input-side logic cone and operated on the same clock signal as the macro is classified as a control type, and a flipflop which has a data output connected to an input terminal of the macro directly or through the input-side logic cone and operated on a different clock signal is classified as a hold type. In the flipflop-replaced netlist, the flipflop classified as the control type is replaced with a control flipflop which is configurable to toggle a data output thereof in synchronization with the clock signal by configuring a control input separately provided a data input thereof, and the flipflop classified as the hold type is replaced with a first hold flipflop which is configurable to hold data so that the data hold therein is unchanged.

In another aspect of the present invention, an integrated circuit design apparatus is provided with a processing unit programmed to classify flipflops arranged around a macro based on a netlist of a integrated circuit incorporating the flipflops and the macro and to generate a flipflop-replaced netlist from the netlist. When the flipflops arranged around the macro are classified, a flipflop which is connected to an input terminal of the macro directly or through an input-side logic cone and operated on the same clock signal as the macro is classified as a control type, and a flipflop which has a data output connected to an input terminal of the macro directly or through the input-side logic cone and operated on a different clock signal is classified as a hold type. In the flipflop-replaced netlist, the flipflop classified as the control type is replaced with a control flipflop which is configurable to toggle a data output thereof in synchronization with the clock signal by configuring a control input separately provided a data input thereof, and the flipflop classified as the hold type is replaced with a first hold flipflop which is configurable to hold data so that the data held therein is unchanged.

In still another aspect of a present invention, a semiconductor integrated circuit is provided with a macro, a control flipflop having a data output connected to an input terminal of the macro directly or through an input-side logic cone and operating on the same clock signal as the macro, and a hold flipflop having a data output connected to an input terminal of the macro directly or through an input-side logic cone and operating on a different clock signal. The control flipflop is configurable to toggle a data output thereof in synchronization with the clock signal by configuring at least one control input separately provided a data input thereof. The hold flipflop is configurable to hold data so that the data held therein is unchanged.

The present invention effectively reduces the number of test patterns required to implement a macro boundary test for detecting a delay error between a macro and a user logic circuit.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit diagram showing an exemplary configuration of a conventional semiconductor integrated circuit;

FIG. 2 is a conceptual view showing an exemplary configuration of a semiconductor integrated circuit in one embodiment of the present invention;

FIG. 3 is a circuit diagram showing an exemplary configuration of a control flipflop integrated in the semiconductor integrated circuit shown in FIG. 2;

FIG. 4 is a circuit diagram showing an exemplary configuration of an observation flipflop integrated in the semiconductor integrated circuit shown in FIG. 2;

FIG. 5 is a circuit diagram showing an exemplary configuration of a hold flipflop integrated in the semiconductor integrated circuit shown in FIG. 2;

FIG. 6 is a conceptual view showing another exemplary configuration of a semiconductor integrated circuit in one embodiment of the present invention;

FIG. 7 is a flowchart showing an exemplary procedure of an integrated circuit design method in one embodiment;

FIGS. 8A and 8B are flowcharts showing an exemplary procedure for classifying a flipflop in this embodiment; and

FIG. 9 is a conceptual view showing a semiconductor integrated circuit design apparatus for executing the integrated circuit design method shown in FIG. 7.

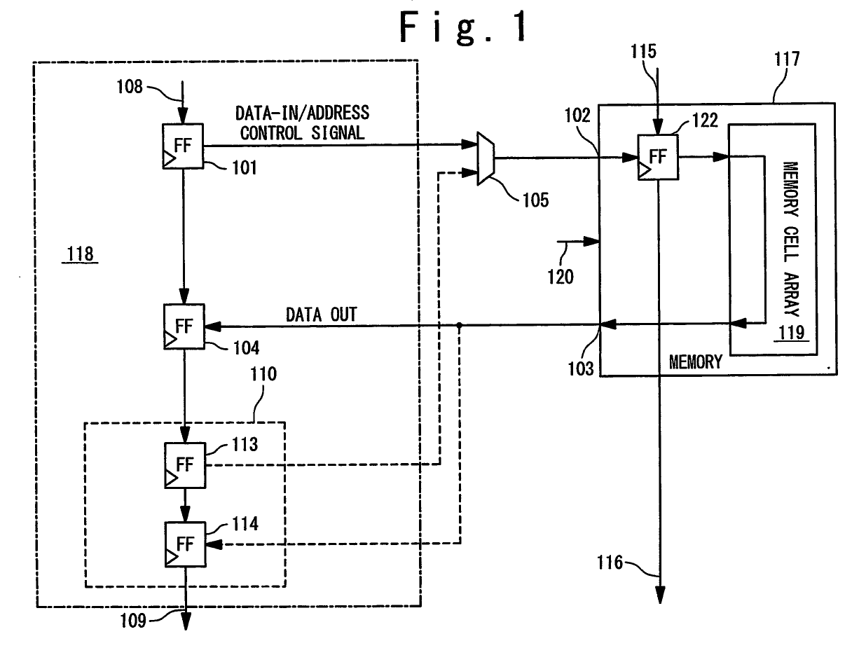

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

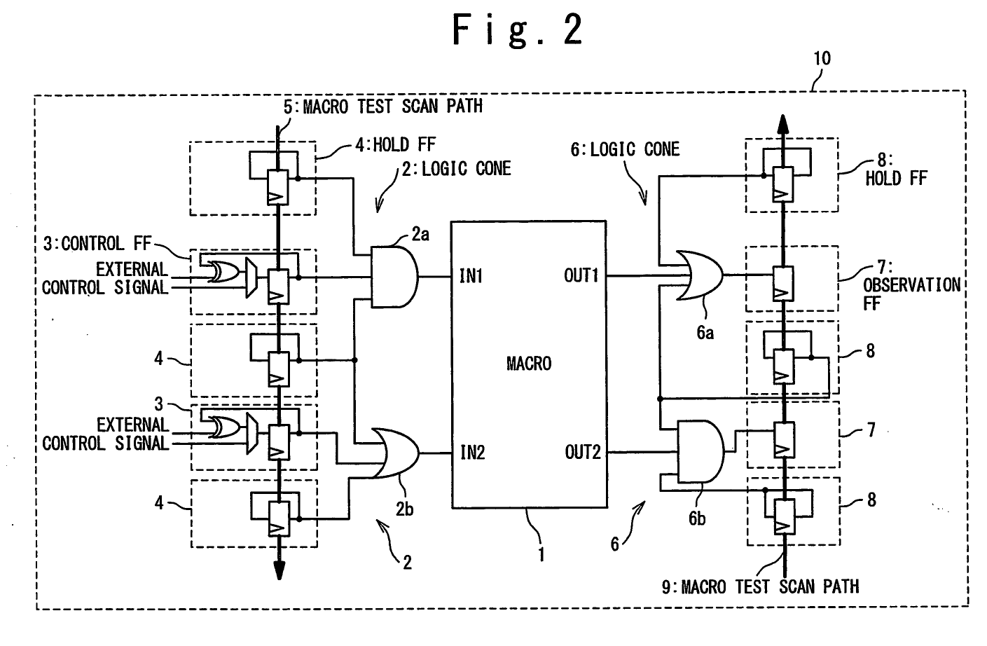

FIG. 2 is the conceptual view showing an exemplary configuration of a semiconductor integrated circuit in one embodiment of the present invention. The semiconductor integrated circuit of this embodiment is designed in accordance with the concept of the design for testability. Specifically, the semiconductor integrated circuit of this embodiment incorporates flipflops specially designed for function tests within the scan path. In the following, a description is given of the semiconductor integrated circuit of this embodiment, which is denoted by the numeral 10 in FIG. 2.

The semiconductor integrated circuit 10 contains a macro 1 and flipflops connected to input terminals IN1 and IN2 of the macro 1 through logic cones 2. In the example in FIG. 2, the logic cone 2 connected to the input terminal IN1 of the macro 1 is provided with an AND gate 2a, and the logic cone 2 connected to the input terminal IN2 is provided with an AND gate 2b.

The flipflops connected to the input terminals IN1 and IN2 through the logic cones 2 include control flipflops 3 operated on the same clock signal as the macro 1 and hold flipflops 4 operated on a different clock signal. The control flipflops 3 are configured to toggle the data output thereof in response to an external control signal. The hold flipflops 4 are configured to keep the value held therein unchanged in response to an external control signal. When a macro boundary test is executed, the control flipflops 3 and the hold flipflops 4 are incorporated into a macro test scan path 5, which is used to set initial values of the control flipflops 3 and the hold flipflops 4. The configurations of the control flipflop 3 and the hold flipflops 4 will be described later in detail.

The semiconductor integrated circuit 10 further includes flipflops which receive data from logic cones 6 connected to output terminals OUT1 and OUT2 of the macro 1. In the example in FIG. 2, the logic cone 6 connected to the output terminal OUT1 of the macro 1 is provided with an OR gate 6a, and the logic cone 6 connected to the output terminal OUT2 is provided with an AND gate 6b.

The flipflops which receive data from the logic cones 6 include observation flipflops 7 operated on the same clock signal as the macro 1. The observation flipflops 7 receive data outputted from the logic cones 6 in the macro boundary test. In addition, hold flipflops 8 are connected to inputs of the logic cones 6 connected to the data inputs of the observation flipflops 7. The hold flipflops 8 are configured to keep the value held therein unchanged in response to an external control signal, similarly to the hold flipflops 4. When a macro boundary test is executed, the observation flipflops 7 and the hold flipflops 8 are incorporated into a macro test scan path 9, which is used for outputting data from the observation flipflops 7 and for setting the hold flipflops 8 with desired initial values. The configurations of the observation flipflops 7 and the hold flipflops 8 will be described later in detail.

It should be noted that, FIG. 2 only shows the concept of the configuration of the semiconductor integrated circuit 10, and an actual semiconductor integrated circuit may be configured more complicatedly. It should be also noted that, although FIG. 2 shows the circuit configuration in which the control flipflops 3 and the hold flipflops 4 are connected to the input terminals IN1 and IN2 of the macro 1 through the logic cones 2, the control flipflops 3 and the hold flipflops 4 may be directly connected to the input terminals of the macro 1. Correspondingly, although FIG. 2 shows the configuration in which the observation flipflops 7 are connected to the output terminals OUT1 and OUT2 of the macro 1 through the logic cones 6, the observation flipflops 7 may be directly connected to the output terminals of the macro 1.

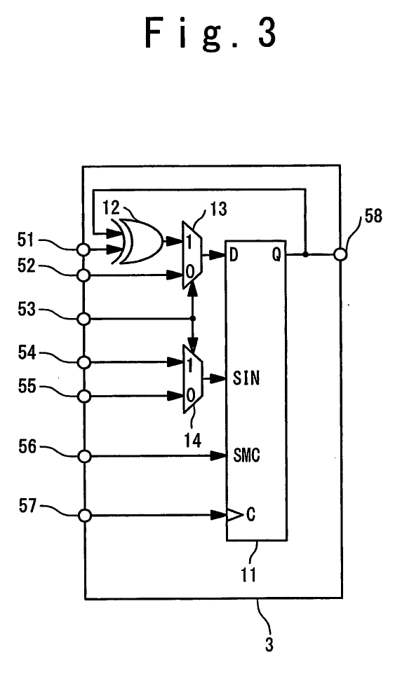

In the following, a description is given of the configurations of the control flipflops 3, the hold flipflops 4, the observation flipflops 7 and the hold flipflops 8. FIG. 3 is a circuit diagram showing an exemplary configuration of the control flipflops 3. The control flipflops 3 are each provided with a scan flipflop 11, an XOR gate 12 and selectors 13, 14. The control flipflops 3 each have a data output 58 and seven inputs: an external control input 51, a data input 52, a macro test mode switching input 53, a macro test scan input 54, a one-chip test scan input 55, an SMC input 56 and a clock input 57. Here, the external control input 51 is used to receive the external control signal supplied from an external device (such as, a tester). The data input 52 is used to receive data from another logic circuit integrated in the semiconductor integrated circuit 10. The macro test mode switching input 53 is used to receive a macro test mode switching signal indicative of the type of the test to be executed among a macro boundary test and an operational test for the entire semiconductor integrated circuit 10. The macro test scan input 54 is connected to data output of another scan flipflop (including a control flipflop 3 or a hold flipflop 4) within the macro test scan path 5, which is a scan path used for the macro boundary test. On the other hand, the one-chip test scan input 55 is connected to a data output of another scan flipflop within a scan path used in the entire operational test of the semiconductor integrated circuit 10. The SMC input 56 is used to receive a scan mode control signal. The clock input 57 is used to receive a clock signal.

The scan flipflop 11 has a function similar to that of a commonly-used scan flipflop. That is, when a scan mode control input SMC is activated (namely, when the scan mode control input SMC is set to “1” in this embodiment), the scan flipflop 11 latches and holds data fed to a scan input SIN in synchronization with the clock signal inputted to the clock input C. On the other hand, when the scan mode control input SMC is deactivated (namely, the scan mode control input SMC is set to “0” in this embodiment), the scan flipflop 11 executes the operation similar to a commonly-used flipflop; the scan flipflop 11 latches and holds data fed to the data input D in synchronization with the clock signal fed to the clock input C. The scan flipflop 11 outputs the latched data from a data output Q. The data output Q of the scan flipflop 11 is connected to the data output 58, the scan mode control input SMC is connected to the SMC input 56, and the clock input C of the scan flipflop 11 is connected to the clock input 57.

The XOR gate 12 has two inputs, one of which is connected to the data output Q of the scan flipflop 11, and the other is connected to the external control input 51. The output of the XOR gate 12 is connected to one input of the selector 13.

The selector 13 has two inputs, one of which is connected to the output of the XOR gate 12, and the other is connected to the data input 52. The output of the selector 13 is connected to the data input D of the scan flipflop 11, and the control input of the selector 13 is connected to the macro test mode switching input 53. The selector 13 selects one of the output of the XOR gate 12 and the data input 52 in response to the macro test mode switching signal fed to the macro test mode switching input 53. In detail, when the macro test mode switching signal is set to “1”, the selector 13 feeds the data outputted from the XOR gate 12 to the data input D of the scan flipflop 11. On the other hand, when the macro test mode switching signal is set to “0”, the data supplied to the data input 52 is fed to the data input D of the scan flipflop 11.

The selector 14 has two inputs, one of which is connected to the macro test scan input 54, and the other input is connected to the one-chip test scan input 55. The output of the selector 14 is connected to the scan input SIN of the scan flipflop 11. When the macro test mode switching signal is set to “1”, the selector 14 feeds the data inputted to the macro test scan input 54 to the scan input SIN of the scan flipflop 11. On the other hand, when the macro test mode switching signal is set to “0”, the data fed to the one-chip test scan input 55 is supplied to the scan input SIN of the scan flipflop 11.

The control flipflops 3, which are configured as described above, operate similarly to commonly-used scan flipflops, when the macro test mode switching signal is set to “0”. In addition, the control flipflops 3 operate to toggle the data output 58 in synchronization with the clock signal fed to the clock input 57, when both of the external control signal and the macro test mode switching signal are set to “1”. As described later, such operations of the control flipflops 3 are of importance in executing the macro boundary test.

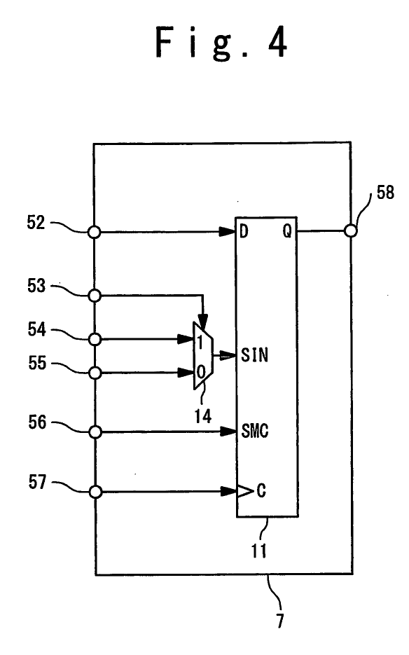

FIG. 4 is the circuit diagram showing the configuration of the observation flipflops 7. The observation flipflops 7 have the configuration in which the XOR gate 12, the selector 13 and the external control input 51 are removed from the control flipflops 3 with the data input D of the scan flipflop 11 connected to the data input 52. The macro test scan input 54 of an observation flipflop 7 is connected to the data output of another scan flipflop (this may be another observation flipflops 7 and the hold flipflops 8) within the macro test scan path 9, which is the scan path used for the macro boundary test, and the one-chip test scan input 55 is connected to the data output of another scan flipflop within the scan path used for the entire operational test of the semiconductor integrated circuit 10.

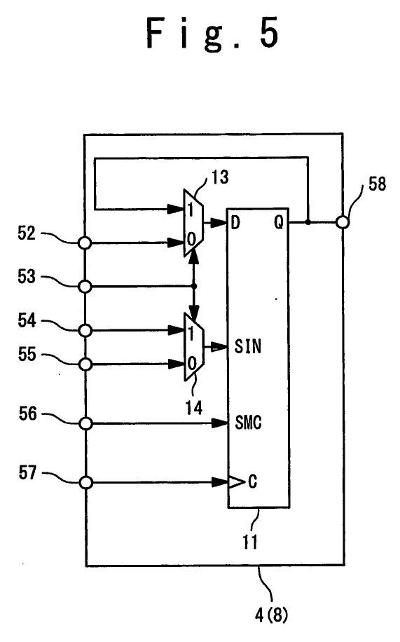

FIG. 5 is the circuit diagram showing an exemplary configuration of the hold flipflops 4 and 8. The hold flipflops 4 and 8 have the configuration in which the XOR gate 12 and the external control input 51 are removed from the control flipflops 3 with one input of the selector 13 connected to the data output Q of the scan flipflop 11, and the other input connected to the data input 52. The macro test scan input 54 of a hold flipflop 4 is connected to the data output of another scan flipflop (this may be the control flipflops 3 and the other hold flipflops 4) configuring the macro test scan path 5. Similarly, the macro test scan input 54 of a hold flipflop 8 is connected to the data output of another scan flipflop (which may be an observation flipflop 7 or another hold flipflop 8) within the macro test scan path 9.

The hold flipflops 4 and 8 thus configured keep the value of the data output 58 unchanged, when the macro test mode switching input 53 is set to “1”. As described later, such operation of the hold flipflops 4 and 8 is important in executing the macro boundary test.

It should be noted that all of the control flipflops 3, the hold flipflops 4, the observation flipflops 7 and the hold flipflops 8 are configured so that one of the macro test scan input 54 and the one-chip test scan input 55 is selectively connected to the scan input SIN of the scan flipflop 11 by the selector 14. Such configuration is directed to improve the easiness of the macro boundary test by forming different scan paths between the macro boundary test and the entire operational test within the semiconductor integrated circuit 10. When the macro test mode switching input is set to “1”, the control flipflops 3, the hold flipflops 4, the observation flipflops 7 and the hold flipflops 8 are incorporated into the macro test scan paths 5 and 9. When the macro test mode switching input is set to “0”, on the other hand, the control flipflops 3, the hold flipflops 4, the observation flipflops 7 and the hold flipflops 8 are incorporated into a scan path used in the entire operational test of the semiconductor integrated circuit 10. The circuit configuration in which the macro test scan paths 5 and 9 used in the macro boundary test are prepared separately from scan paths used for the entire operational test of the semiconductor integrated circuit 10 effective reduces the number of flipflops within the macro test scan paths 5 and 9. This facilitates the preparation of the test patterns for the macro boundary test. It should be noted that a scan path used for the entire operational test of the semiconductor integrated circuit 10 may be also used for the macro boundary test in principle. In this case, the selector 14 and the macro test scan input 54 may be removed from the control flipflops 3, the hold flipflops 4, the observation flipflops 7 and the hold flipflops 8 with the scan input SIN of the scan flipflop 11 directly connected to the one-chip test scan input 55.

It should be noted that the control flipflops 3, the hold flipflops 4, the observation flipflops 7 and the hold flipflops 8 can be all formed by modifying a typical configuration of a commonly-used scan flipflop. In one embodiment, the control flipflops 3, the hold flipflops 4, the observation flipflops 7 and the hold flipflops 8 are configured by adding one or more additional circuit layers (or wrappers) to a commonly-used scan flipflop and preparing input terminals for the additional circuit layers. The control flipflops 3, the hold flipflops 4, the observation flipflops 7 and the hold flipflops 8 may be configured with combinations of scan flipflops, selectors and XOR gates, which are all primitive blocks.

The procedure for executing the macro boundary test by using the above-configured control flipflops 3, hold flipflops 4, observation flipflops 7 and hold flipflops 8 will be then described below. At first, a scan shifting operation is implemented to set desired initial values to the control flipflops 3, the hold flipflops 4, the observation flipflops 7 and the hold flipflops 8 through the macro test scan paths 5 and 9. Specifically, the macro test mode switching signal is activated, and the macro test mode switching inputs of the control flipflops 3, the hold flipflops 4, the observation flipflops 7 and the hold flipflops 8 are set to “1”. This results in that the control flipflops 3 and the hold flipflops 4 are incorporated into the macro test scan path 5, and the observation flipflops 7 and the hold flipflops 8 are incorporated into the macro test scan path 9. Moreover, the scan mode control signal is activated to set the SMC inputs 56 of the control flipflops 3, the hold flipflops 4, the observation flipflops 7 and the hold flipflops 8 to “1”. In the meantime, the clock signal used for the scan shifting operation is fed to the clock inputs 57 and desired initial values are sequentially supplied through the macro test scan paths 5 and 9. As a result, the desired initial values are set to the control flipflops 3, the hold flipflops 4, the observation flipflops 7 and the hold flipflops 8.

Subsequently, a fault detection target path (namely, a path from a control flipflop 3 to an observation flipflop 7 through the macro 1) is operated at the same frequency as the actual operation. In detail, the SMC inputs 56 of the control flipflops 3, the hold flipflops 4, the observation flipflops 7 and the hold flipflops 8 are set to “0”, and the clock signal of the same frequency as the actual operation is fed to the clock inputs 57 of the control flipflops 3, the hold flipflops 4, the observation flipflops 7 and the hold flipflops 8 from an internal clock circuit integrated in the semiconductor integrated circuit 10. As a result, a signal is transmitted from the control flipflop 3 to the macro 1 through the logic cone 2, and another signal is transmitted from the macro 1 to the observation flipflop 7 through the logic cone 6. Moreover, the supply of the clock signal is stopped to terminate the operation of the fault detection target path.

In the meantime, the data outputs 58 of the hold flipflops 4 and 8 are fixed to the desirable initial values in response to the SMC inputs 56 being set to “0”. This addresses properly operating the fault detection target path in the macro boundary test. If the output values of the hold flipflops 4 and 8 are incorrectly set, the signal transmitted over the fault detection target path may be masked by the outputs of the hold flipflops 4 and 8 without toggling the value thereof, even when the output values of the control flipflops 3 are toggled. This is not preferable in successfully executing the macro boundary test. In this embodiment, the macro boundary test is successfully executed by fixing the data outputs 58 of the hold flipflops 4, 8 to the desired initial values. It should be noted that fixing the data outputs 58 of the hold flipflops 4 and 8 does not cause any problem in circuit operations in the macro boundary test, since the fault detection target path is comprised of paths between the macro 1 and the flipflops operated at the same clock as the macro 1, and the hold flipflops 4 and 8 operate on different clock signals from the clock signal on which the macro 1 operates.

Subsequently, the data held in the observation flipflops 7 are externally outputted through the macro test scan path 9, and the delay error of the fault detection target path is detected on the basis of the output data.

An advantage of such a testing method is that the number of test patterns necessary for the macro boundary test is reduced. In the semiconductor integrated circuit 10 in this embodiment, the data outputs 58 of the control flipflops 3 are allowed to be toggled independently of the values of the data inputs 52 thereof by appropriately setting the values of the external control signal and the macro test mode switching signal. The test patterns required to toggle the data outputs 58 of the control flipflops 3 only include test patterns required to set the external control signal and the macro test mode switching signal, and toggling the data outputs 58 of the control flipflops 3 can be achieved by a reduced number of test patterns. The initial values of the data outputs 58 to be toggled may be set by an external device with the macro test scan paths 5 and 9, as mentioned above. The test patterns may be generated such that the data outputs 58 of the control flipflops 3 are toggled after the initial value setting. The test patterns used for the initial value setting may be designed to be added if necessary. In this embodiment, it is not necessary to generate test patterns so that all of the data inputs to the logic cones connected to the data inputs 52 of the control flipflops 3 are controlled. As discussed above, the semiconductor integrated circuit 10 of this embodiment allows executing the macro boundary test by using a reduced number of test patterns.

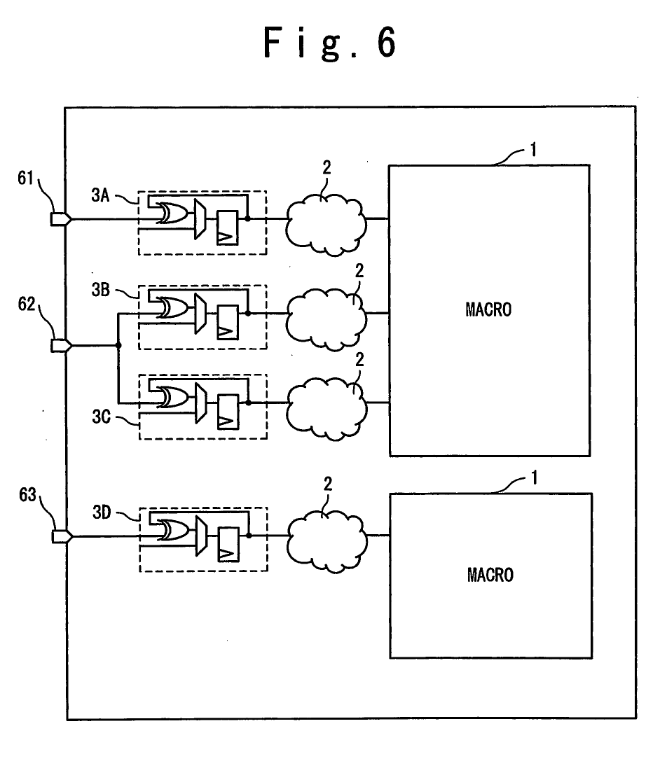

It should be noted that different external control signals may be supplied to different control flipflops 3, as shown in FIG. 6, when a plurality of control flipflops 3 are integrated within in the semiconductor integrated circuit 10. In the example of FIG. 6, an external control signal from an external control terminal 61 is supplied to the external control input 51 of a control flipflop 3A. On the other hand, an external control signal from an external control terminal 62 is supplied to the external control inputs 51 of control flipflops 3B and 3C. Also, an external control signal from an external control terminal 63 is supplied to the external control input 51 of a control flipflop 3D. Such configuration allows independently setting the operations of the respective control flipflops, facilitating the preparation of the test patterns for the macro boundary test.

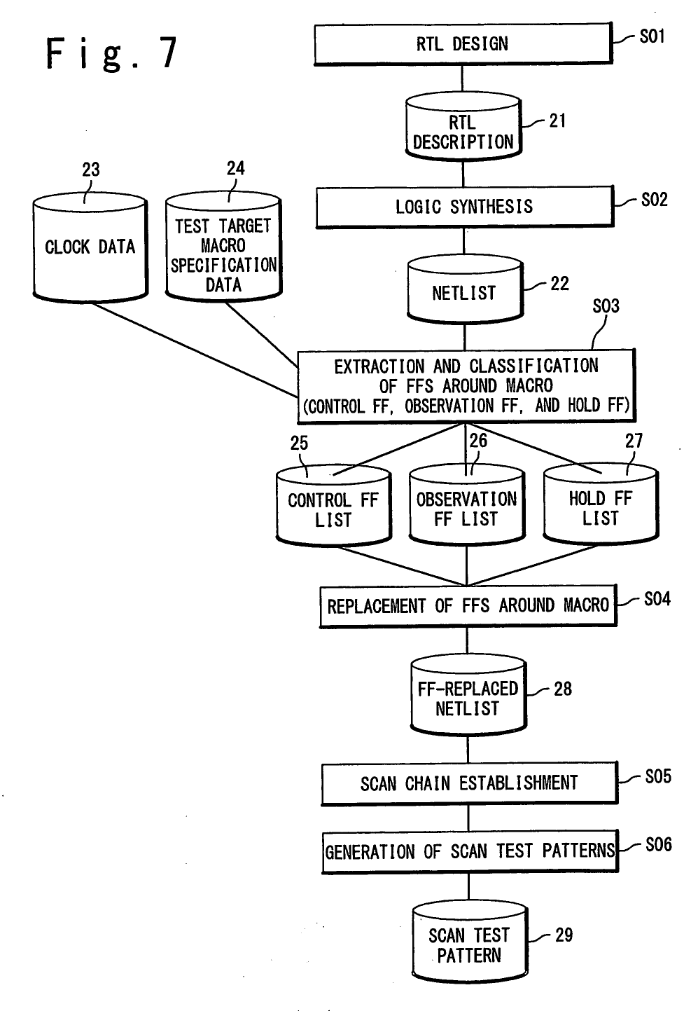

Next, a description is given of the method of designing the semiconductor integrated circuit 10 in this embodiment. FIG. 7 is a flowchart showing an exemplary procedure for designing the semiconductor integrated circuit 10 in this embodiment. As shown in FIG. 7, the procedure begins with an RTL (Register Transfer Level) design for generating an RTL description 21 of the semiconductor integrated circuit 10 at Step S01. This is followed by implementing a logical synthesis on the RTL description 21 to generate a netlist 22 corresponding to the RTL description 21 at Step S02. The netlist 22 describes components and connections therebetween in the semiconductor integrated circuit 10. That is, the netlist 22 describes the connections between the macros and the flipflops arranged around the macros.

Subsequently, the flipflops positioned around the macros to be subjected to the macro boundary test (hereinafter referred to as the test target macros) are extracted for each of the test target macros. In addition, flipflops satisfying particular requirements out of the extracted flipflops are classified into three types: a control type, an observation type and a hold type, at Step S03. In this classification, the above-described netlist 22 and clock data 23 specifying clock signals fed to the respective flipflops and respective macros are referred to. In addition, the macros to be subjected to the test are specified by test target macro specification data 24.

More specifically, (1) a flipflop connected to an input terminal of the test target macro directly or through a logic cone and operated on the same clock signal as the macro is classified as the control type, and (2) a flipflop connected to an output terminal of the test target macro directly or through a logic cone and operated on the same clock signal as the macro is classified as the observation. In addition, (3a) a flipflop connected to an input terminal of the test target macro directly or through the logic cone and operated on a clock signal different from that of the macro, and (3b) a flipflop connected to an input of a logic cone connected to the data input of a flipflop classified as the observation type are classified as the hold type. The procedure for classifying the flipflop will be described later in detail. Three flipflop lists: a control flipflop list 25 which lists the flipflops classified as the control type, an observation flipflop list 26 which lists the flipflops classified as the observation type, and a hold flipflop list 27 which lists the flipflops classified as the hold type are generated at Step S03.

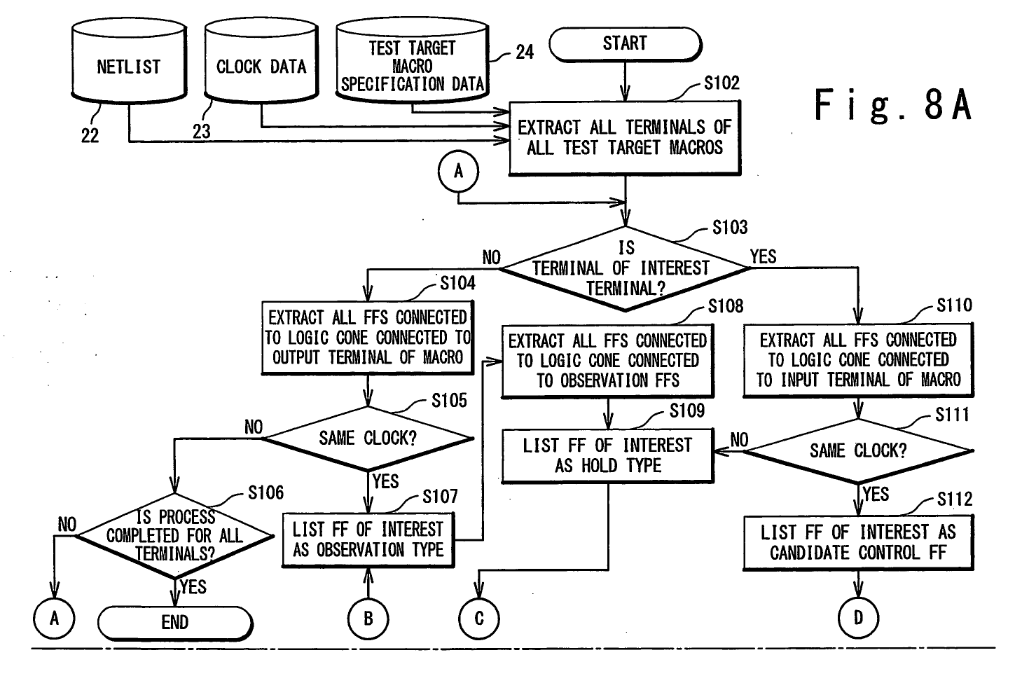

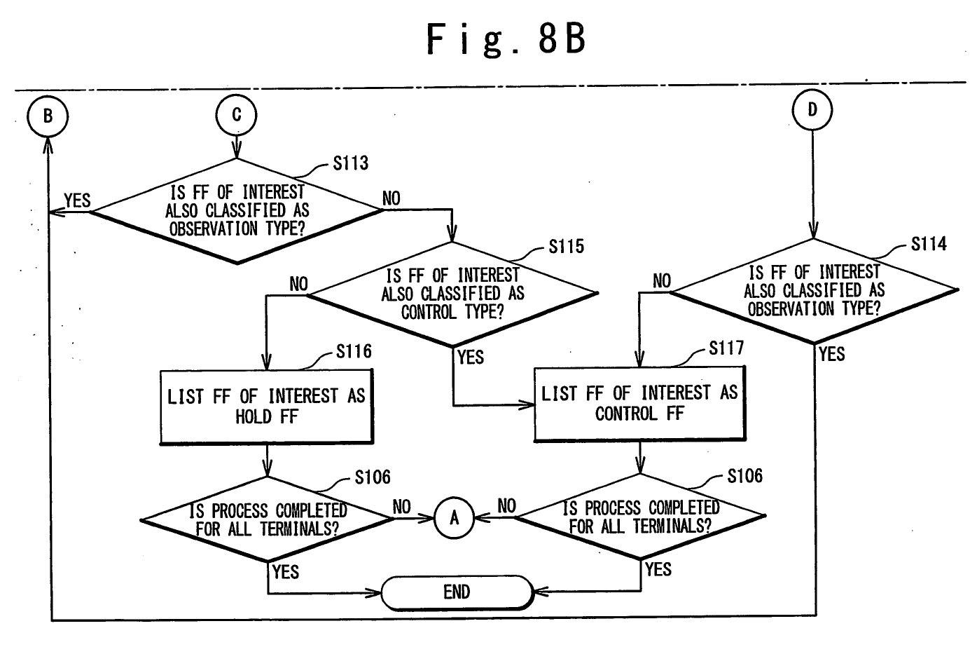

FIGS. 8A and 8B are flowcharts showing details of the classifying procedure at Step S03. As shown in FIG. 8A, the classifying procedure begins with extracting all the terminals in all the test target macros from the netlist 22 at Step S102. The following processes are performed on each terminal of each test target macro.

When the terminal of interest is an output terminal of the test target macro of interest, all of the flipflops connected to the output of the logic cone connected to the output terminal of interest are extracted at Step S104. When the flipflops extracted at the step S104 do not include a flipflop operated on the same clock signal as the test target macro, the process jumps to Step S106. When a certain flipflop out of the flipflops extracted at the step S104 is operated on the same clock signal as the test target macro, on the other hand, the flipflop is classified as the observation type and listed in the observation flipflop list 26 (Step S107). Furthermore, flipflops connected to the inputs of the logic cones connected to the data inputs of the flipflops classified as the observation type are extracted (Step S108). The flipflops extracted at the step S108 are listed as candidate hold flipflops (Step S109). It should be noted that a candidate hold flipflop is merely a “candidate” which may be classified as the hold type later, and is not finally classified as the hold type at this stage.

On the other hand, when the terminal of interest is an input terminal of the test target macro of interest, all the flipflops connected to the inputs of the logic cone connected to the input terminal of are extracted at Step S110. Out of the flipflops extracted at the step S110, flipflops operated on the same clock signal as the test target macro are listed as the candidate control flipflop. Here, a candidate control flipflop is merely a “candidate” which may be classified as the control type, and is not finally classified as the control type at this stage. On the other hand, among the flipflops extracted at Step S104, flipflops operated on a clock signal different from the clock signal on which the test target macro of interest operates are listed as the candidate hold flipflop at Step S109.

With reference to FIG. 8B, the types of the respective flipflops listed as the candidate control flipflops and the candidate hold flipflops at Steps S108 and S113 are finally determined as follows. When a certain flipflop listed up as the candidate control flipflop is also classified as the observation type, this flipflop is classified as the observation type and listed in the observation flipflop list 26 (Step S107). Moreover, when a certain flipflop listed as the candidate control flipflop is not classified as the observation type, this flipflop is classified as the control type and listed in the control flipflop list 25 at Step S117. When a certain flipflop listed as the candidate hold flipflop is also classified as the observation type at Step S113, on the other hand, this flipflop is classified as the observation type and listed up in the observation flipflop list 26 at Step S107. Also, when a certain flipflop listed up as the candidate hold flipflop is not classified as the observation type but as the control type, the flipflop is classified as the control type at Step S117. Finally, when a certain flipflop listed up as the candidate hold flipflop is not classified as the observation type or the control type, this flipflop is classified as the hold type and listed up in the hold flipflop list 27 at Step S116.

When the types of all the flipflops listed up as the candidate control flipflop and the candidate hold flipflop are determined, the process for the terminal of interest is completed, and the procedure proceeds to Step S106.

At Step S106, it is judged whether or not the foregoing process has been performed on all the terminals of the macro of interest. When a certain terminal is not subjected to the foregoing process, the foregoing process is performed on the terminal. When the foregoing process has been performed on all of the terminals, the classification of the flipflops is completed.

After the classification of the flipflops, the netlist 22 is modified so that the flipflops classified as the control type, the observation type and the hold type are replaced with control flipflops, observation flipflops and hold flipflops shown in FIGS. 3, 4 and 5, respectively to generate a flipflop-replaced netlist 28 from the netlist 22 at Step S04. In the flipflop-replaced netlist 28, the flipflops classified as the control type, the observation type and the hold type are replaced with the control flipflops, the observation flipflops and the hold flipflops shown in FIGS. 3, 4 and 5, respectively.

Subsequently, a scan chain synthesis is performed on the flipflop-replaced netlist 28 for establishing scan chains at Step S05. The scan chain synthesis involves inserting scan flipflops and implementing routing for the inserted scan flipflops and the above-described control flipflops, observation flipflops and hold flipflops.

Moreover, scan test patterns 29 are generated at Step S06, and the design procedure for the semiconductor integrated circuit 10 in this embodiment is completed as mentioned above.

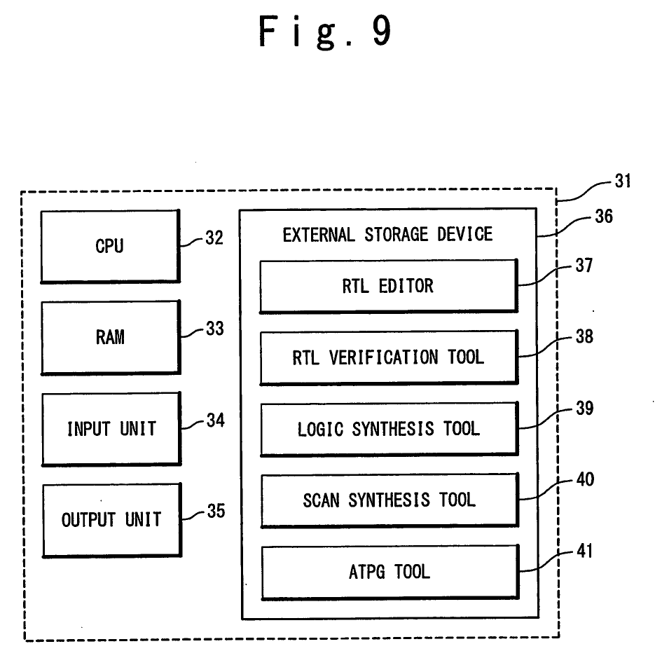

FIG. 9 is the conceptual view showing an exemplary configuration of a semiconductor integrated circuit design apparatus 31 for executing the method of designing the above-described semiconductor integrated circuit. The semiconductor integrated circuit design apparatus 31 is provided with a CPU 32, a RAM 33, an input unit 34, an output unit 35 and an external storage unit 36. Various software programs used to execute the above-described integrated circuit design method, including an RTL editor 37, an RTL verification tool 38, a logic synthesis tool 39, a scan synthesis tool 40 and an ATPG (Automatic Test Pattern Generation) tool 41, are installed onto the external storing unit 36.

In detail, the RTL editor 37 and the RTL verification tool 38 are used for the RTL design shown in FIG. 7 at Step S01. The logic synthesis at Step S02 is executed by the logic synthesis tool 39, and the classification and replacement of the flipflops at Steps S03 and S04 and the establishment of the scan chain at Step S05 are executed by the scan synthesis tool 40. Moreover, the scan test patterns are generated by the scan synthesis tool 40. The various data generated at the respective steps of the integrated circuit design procedure shown in FIG. 7 (for example, the RTL description 21, the net list 22, the control flipflop list 25, the observation flipflop list 26, the hold flipflop list 27 and the flipflop-replaced netlist 28) are stored in the external storage unit 36, and the stored data are used in the following steps.

As thus described, the integrated circuit design method and the semiconductor integrated circuit design apparatus 31 of this embodiment allows designing a semiconductor integrated circuit in which control flipflops 3, hold flipflops 4, observation flipflops 7 and hold flipflops 8 are incorporated at appropriate positions, while reducing the number of the test patterns necessary for the macro boundary test.

It is apparent that the present invention is not limited to the above embodiments, but may be modified and changed without departing from the scope of the invention.

What is claimed is:

1. An integrated circuit design method comprising:
classifying flipflops arranged around a macro based on a netlist of a integrated circuit incorporating said flipflops and said macro; and
generating a flipflop-replaced netlist from said netlist,
wherein, in said classifying, a flipflop which is connected to an input terminal of said macro directly or through an input-side logic cone and operated on the same clock signal as said macro is classified as a control type, and a flipflop which has a data output connected to an input terminal of said macro directly or through said input-side logic cone and operated on a different clock signal is classified as a hold type,
wherein, in said flipflop-replaced netlist, said flipflop classified as said control type is replaced with a control flipflop which is configurable to toggle a data output thereof in synchronization with said clock signal by configuring a control input separately provided a data input thereof, and said flipflop classified as said hold type is replaced with a first hold flipflop which is configurable to hold data so that said data held therein is unchanged.

2. The integrated circuit design method according to claim 1, wherein, in said classifying, a flipflop has a data input connected to an output terminal of said macro directly or through an output-side logic cone and operated on the same clock signal as said macro is classified as an observation type, and
wherein, in said flipflop-replaced netlist, said flipflop classified as said observation type is replaced with an observation flipflop configured to receive data from said output logic cone.

3. The integrated circuit design method according to claim 2, wherein, in said classifying, a flipflop which has a data output connected to an input of said output-side logic cone is classified as said hold type, and
wherein, in said flipflop-replaced netlist, said flipflop classified as said hold type and having said data output connected to said input of said output-side logic cone is replaced with a second hold flipflop which is configurable to hold data so that said data held therein is unchanged.

4. The integrated circuit design method according to claim 1, wherein said at least one control input of said control flipflop includes first and second control inputs, and
wherein said control flipflop includes:
a first scan flipflop;
an XOR gate; and
a first selector,
wherein said XOR gate has a first input connected to a data output of said first scan flipflop, a second input connected to said first control input, and an output connected to an first input of said first selector,
wherein a second input of said first selector is connected to said data input of said control flipflop and an output of said first selector is connected to a data input of said scan flipflop, and
wherein a control signal for controlling said first selector is fed to said second control input.

5. The integrated circuit design method according to claim 1, wherein said first hold flipflop includes:
a second scan flipflop; and
a second selector,
wherein said second selector has a first input connected to a data output of said second scan flipflop, a second input connected to a data input of said first hold flipflop, and an output connected to said data input of said second scan flipflop, and
wherein a control signal for controlling said second selector is fed to said control input of said first hold flipflop.

6. The integrated circuit design method according to claim 1, wherein said at least one control flipflop includes first and second control flipflops,
wherein said control input of said first control flipflop is fed with a first control signal, and
wherein said control input of said second control flipflop is fed with a second control signal provided separately from said first control signal.

7. An integrated circuit design apparatus comprising:
a processing unit programmed to classify flipflops arranged around a macro based on a netlist of a integrated circuit incorporating said flipflops and said macro and to generate a flipflop-replaced netlist from said netlist,
wherein, when said flipflops arranged around said macro are classified, a flipflop which is connected to an input terminal of said macro directly or through an input-side logic cone and operated on the same clock signal as said macro is classified as a control type, and a flipflop which has a data output connected to an input terminal of said macro directly or through said input-side logic cone and operated on a different clock signal is classified as a hold type,
wherein, in said flipflop-replaced netlist, said flipflop classified as said control type is replaced with a control flipflop which is configurable to toggle a data output thereof in synchronization with said clock signal by configuring a control input separately provided a data input thereof, and said flipflop classified as said hold type is replaced with a first hold flipflop which is configurable to hold data so that said data held therein is unchanged.

8. A semiconductor integrated circuit comprising:
a macro;
at least one control flipflop having a data output connected to an input terminal of said macro directly or through an input-side logic cone and operating on the same clock signal as said macro; and
a first hold flipflop having a data output connected to an input terminal of said macro directly or through an input-side logic cone and operating on a different clock signal,
wherein said control flipflop is configurable to toggle a data output thereof in synchronization with said clock signal by configuring at least one control input separately provided a data input thereof, and
wherein said first hold flipflop is configurable to hold data so that said data held therein is unchanged.

9. The semiconductor integrated circuit according to claim 8, further comprising:
an observation flipflop having a data input connected to an output terminal of said macro directly or through an output-side logic cone and operating on the same clock signal as said macro.

10. The semiconductor integrated circuit according to claim 8, further comprising:
a second hold flipflop having a data output connected to an input of said output-side logic cone,
wherein said second hold flipflop is configurable to hold data so that said data held therein is unchanged.

11. The semiconductor integrated circuit according to claim 8, wherein said at least one control input of said control flipflop includes first and second control inputs, and
wherein said control flipflop includes:
a first scan flipflop;
an XOR gate; and
a first selector,
wherein said XOR gate has a first input connected to a data output of said first scan flipflop, a second input connected to said first control input, and an output connected to an first input of said first selector,
wherein a second input of said first selector is connected to said data input of said control flipflop and an output of said first selector is connected to a data input of said scan flipflop, and
wherein a control signal for controlling said first selector is fed to said second control input.

12. The semiconductor integrated circuit according to claim 8, wherein said first hold flipflop includes:
a second scan flipflop; and
a second selector,
wherein said second selector has a first input connected to a data output of said second scan flipflop, a second input connected to a data input of said first hold flipflop, and an output connected to said data input of said second scan flipflop, and
wherein a control signal for controlling said second selector is fed to said control input of said first hold flipflop.

13. The semiconductor integrated circuit according to claim 8, wherein said at least one control flipflop includes first and second control flipflops,
wherein said control input of said first control flipflop is fed with a first control signal, and
wherein said control input of said second control flipflop is fed with a second control signal provided separately from said first control signal.
